(19) United States
(12) Patent Application Publication
(10) Pub. No.: US 2025/0038099 A1
(43) Pub. Date: Jan. 30, 2025

(54) POWER SEMICONDUCTOR INTEGRATED UNIT AND POWER CONVERTER CIRCUIT STRUCTURE THEREOF, AND LOOP STRUCTURE WITH INTEGRATED UNITS CONNECTED IN PARALLEL

(71) Applicant: CAMBRIDGE INTEGRATION LTD, Cambridge (GB)

(72) Inventors: Ameer Hussein Abd JANABI, Baghdad (IQ); Teng LONG, Beijing (CN)

(73) Assignee: CAMBRIDGE INTEGRATION LTD, Cambridge (GB)

(21) Appl. No.: 18/760,451

(22) Filed: Jul. 1, 2024

(30) Foreign Application Priority Data
Jun. 29, 2023 (CN) 202310787722.5
Feb. 27, 2024 (CN) 202410216758.2

(51) Int. Cl. H01L 23/498; H01L 23/00; H01L 23/13; H01L 23/367; H01L 25/10

(52) U.S. Cl. CPC H01L 23/4985; H01L 23/13; H01L 23/3675; H01L 25/105; H01L 24/08; H01L 2224/08225; H01L 2225/1005

(57) ABSTRACT

A power semiconductor integrated unit including a substrate with a recess to accommodate a power semiconductor chip, and top surfaces of a source lower-surface pad and a gate pad that are on the same side surface of the power semiconductor chip are or nearly flush with a top surface of a base plate. A flexible printed circuit board connects to the substrate and power semiconductor chip, the flexible printed circuit board has source and gate conductive traces, the source conductive trace connects to the source lower-surface pad on a top side of the chip, and the gate conductive trace connects to the gate pad on the top side of the chip. The flexible printed circuit board has an epitaxial portion, and the gate conductive trace and the source conductive trace extend onto the epitaxial portion. The integrated unit also includes a power converter circuit structure and a parallel loop structure.

### TECHNICAL FIELD

The present invention relates to a power semiconductor integrated unit and a power converter circuit structure thereof, and a loop structure with integrated units connected in parallel.

### BACKGROUND

Power electronic single-tube devices in conventional packages, such as TO220 and TO247 packages, have large parasitic inductance and a long gate drive circuit, and are mostly in electrical connections using pins. Inside a package, an electrode of a power semiconductor and a pin packaged outward are connected using a bonding wire or a copper row. The connection of the pin packaged outward greatly restricts placement of the pin on a printed circuit board. Each pin needs to penetrate all layers of the printed circuit board. In this case, a wire on each layer of the printed circuit board is interrupted at the pin of the power semiconductor, and thus can only bypass the pin horizontally instead of directly passing through it. This results in additional paths in a main circuit and a gate drive circuit. Consequently, parasitic inductance of the circuit is significantly increased. Due to the pins used in a conventional single-tube device, a distance between the device and a printed circuit board is increased, making it difficult for assembly and mechanical fastening of a heat sink of the device. If a single-tube power semiconductor can be packaged without pins and can be in an outward electrical connection from a surface of the power semiconductor, the single-tube device may be directly attached to a printed circuit board, which only occupies a surface of the printed circuit board and does not affect an internal conductor layout of a multilayer circuit board.

A conventional power electronic single-tube package is not insulated outward, so a heat sink cannot be used directly. A heat-dissipation backplate packaged in a conventional single tube is usually an electrode (mostly a drain or collector, but also a source or an emitter) of a power semiconductor chip. The electrode of the power semiconductor has a potential to the ground and cannot be in direct contact with the ground. However, a heat sink is usually connected to the ground. This means that there is a need to add a layer of insulating film between the heat-dissipation backplate packaged in the conventional single tube and the heat sink, which is also a conventional practice in assembly of the heat sink for the conventional single-tube package. However, the insulating film, limited by a material, usually has poor thermal conductivity, which seriously affects heat dissipation of the conventional single-tube package.

The conventional single-tube package restricts the design of a printed circuit board of a main circuit of a converter, which is not conducive to a parallel connection of single tubes. Due to the pin design of the conventional package, it is difficult to meet requirements of circuit length consistency and circuit symmetry for a parallel connection of multiple tubes through the multilayer conductor layouts of the printed circuit board. This is because the pin penetrates all layers of the printed circuit board, the conductor layouts have to avoid the pin of each single-tube device, which leads to inconsistent and asymmetrical layouts and further causes problems of inconsistency and uneven current sharing of multiple devices connected in parallel.

A single-tube package of a power semiconductor by using the surface-mount technology (SMT) is available in low-power applications, but a bonding wire or row is still used for connection, parasitic inductance is still very large, and the single-tube surface-mount package is still not insulated outward. In the present invention, a new surface-mount single-tube device package is formed with a new geometric structure and design. The surface-mount technology is used for an outward electrical connection of the package without pins. No bonding wire or copper row is used for an internal connection of the package. This design is called a power semiconductor integrated unit. This integrated unit is insulated outward, has lower parasitic inductance, and has a special geometrical shape that allows the integrated unit to have a very symmetrical arrangement and conductor layout on a printed circuit board, which can be effectively used for multiple devices connected in parallel.

### SUMMARY

A technical problem to be resolved in the present invention is to provide a power semiconductor integrated unit on a printed circuit board, to significantly reduce loop parasitic inductance of a power semiconductor device in a power converter, and make it easy to use.

To resolve the foregoing technical problem, the present invention provides the following technical solutions: A power semiconductor integrated unit includes a substrate, where the substrate is provided with an etched recess to accommodate a power semiconductor chip, a bottom surface of the recess is electrically connected to a drain on a bottom surface of the power semiconductor chip, and a source and a gate that are on an upper surface of the power semiconductor chip are flush or nearly flush with a top surface of the substrate; a flexible printed circuit board is connected to the substrate and the power semiconductor chip, the flexible printed circuit board is provided with a source conductive trace and a gate conductive trace, the source conductive trace is connected to the source on a top side of the power semiconductor chip, and the gate conductive trace is connected to the gate on the top side of the power semiconductor chip; the flexible printed circuit board is provided with an epitaxial portion, and the gate conductive trace and the source conductive trace extend onto the epitaxial portion; and the epitaxial portion of the flexible printed circuit board is bendable or is directly connected to a power semiconductor control circuit.

As a preferred solution, a lower layer of the substrate is a thermally-conductive metal layer, a middle layer of the substrate is a ceramic insulation layer, an upper layer of the substrate is an electrically-conductive metal layer, the etched downward recess is provided on the middle of the electrically-conductive metal layer, a recess area is larger than a power semiconductor chip area, and an upper surface of the electrically-conductive metal layer is almost on the same horizontal plane with the source and the gate that are on the surface of the power semiconductor chip; and a drain lower-surface pad on a bottom surface of the flexible printed circuit board is electrically connected to the electrically-conductive metal layer on the upper layer of the substrate.

As a preferred solution, the source of the power semiconductor chip is electrically connected to a source lower-surface pad on an end portion of the source conductive trace on the bottom surface of the flexible printed circuit board; and the gate of the power semiconductor chip is electrically connected to a gate pad on an end portion of the gate conductive trace on the bottom surface of the flexible printed circuit board.

As a preferred solution, a drain lower-surface pad of the flexible printed circuit board is electrically connected to a pad and copper foil on a lower surface through a through hole, and a source lower-surface pad of the flexible printed circuit board is electrically connected to the pad and copper foil on the lower surface through a through hole.

As a preferred solution, the drain lower-surface pad and the source lower-surface pad that are on an upper surface of the flexible printed circuit board are directly electrically connected to two corresponding positions of a circuit of a power converter, as external power connection points packaged in the power semiconductor, and a gate solder joint and a source solder joint that are of the epitaxial portion of the flexible printed circuit board are directly connected to a gate drive circuit of the power converter, as external control connection points packaged in the power semiconductor.

As a preferred solution, the downward recess is larger than an insulating material for partially filling the power semiconductor chip; and a board body of the flexible printed circuit board is made of a highly-insulating and flexible film material.

These solutions have the following beneficial effects: Based on the substrate using a double-sided copper insulating base plate, the packaged integrated unit can be directly connected to an external heat sink. An upper copper surface of the base plate is provided with the etched recess to accommodate the power semiconductor chip, and top surfaces of the source lower-surface pad and the gate pad that are on the same side surface of the power semiconductor chip are flush with a top surface of the base plate, which can maximize negative coupling in a direct-current link and obtain very low loop parasitic inductance. The flexible printed circuit board is provided with the source conductive trace and the gate conductive trace, the source conductive trace is connected to the source lower-surface pad on the top side of the chip, and the gate conductive trace is connected to the gate pad on the top side of the chip. The flexible printed circuit board provides stress relief and allows low-profile interconnections, which helps keep inductance low. The flexible printed circuit board is provided with the I-shaped epitaxial portion, and the gate conductive trace and the source conductive trace extend onto the epitaxial portion. The epitaxial portion of the flexible printed circuit board is bent and penetrates an avoidance slot provided in the main printed circuit board, the gate conductive trace on the epitaxial portion is connected to a conductive trace that is on the main printed circuit board and that connects to a gate plane in a gate driver, and the source conductive trace is connected to a conductive trace on a source plane in the gate driver on the main printed circuit board. This makes the power semiconductor integrated unit on the printed circuit board not only easy to connect to another functional device without damage, but also have good operation performance and heat dissipation.

Another technical problem to be resolved in the present invention is to provide a power converter circuit structure including the foregoing power semiconductor integrated unit on the printed circuit board.

To resolve the foregoing technical problem, the present invention provides the following technical solutions: A power converter circuit structure including the power semiconductor integrated unit on the printed circuit board is provided, where an upper surface of the integrated unit is electrically connected to a bottom surface of a main circuit, the epitaxial portion of the integrated unit is bent and penetrates a main circuit board, and is electrically connected to a control circuit on the main circuit board, the drain lower-surface pad and the source lower-surface pad that are on the upper surface of the flexible printed circuit board in the integrated unit, as external electrical connection points of the integrated unit, are electrically connected to the main circuit on the main circuit board, and the lower surface of the substrate in the integrated unit is partially electrically insulated from a circuit of the integrated unit.

As a preferred solution, the lower surface of the substrate is directly connected to a heat sink.

As a preferred solution, the control circuit is provided on a control circuit board, the control circuit board is disposed on the main circuit board, and the epitaxial portion of the flexible printed circuit board in the integrated unit is bent and penetrates the main circuit board, and is electrically connected to the control circuit board.

These solutions have the following beneficial effects:

The power semiconductor integrated unit and a direct-current link module are disposed on the main circuit board, making the structure simpler, and reducing manufacturing costs.

A part of the power semiconductor integrated unit disposed on the printed circuit board is connected to a liquid cooling device, quickly taking heat away from the chip, and ensuring normal operation of the chip.

Another technical problem to be resolved in the present invention is to provide a loop structure with a plurality of power semiconductor integrated units connected in parallel.

To resolve the foregoing technical problem, the present invention provides the following technical solutions: A loop structure with a plurality of power semiconductor integrated units connected in parallel includes the plurality of power semiconductor integrated units. Every two of all the power semiconductor integrated units are completely coupled, symmetrically provided, and connected in parallel to form a primary unit, every two primary units are completely coupled, symmetrically provided, and connected in parallel to form a secondary unit, and every two lower units are completely coupled, symmetrically provided, and connected in parallel to form an upper unit, and are finally connected to the same drive chip/circuit through a general connection trace.

These solutions have the following beneficial effects: In the loop structure with a plurality of power electronic converters connected in parallel, gate drive circuits of every two of all the power electronic converters are symmetrically provided and connected in parallel to form a primary unit, gate drive circuits of every two primary units are symmetrically provided and connected in parallel to form a secondary unit, and gate drive circuits of every two lower units are symmetrically provided and connected in parallel to form an upper unit, and are finally connected to the same drive chip/circuit through the general connection trace. This gate loop structure allows flux cancellation and minimizes gate loop inductance, improving performance and reducing overall production costs.

### BRIEF DESCRIPTION OF THE DRAWINGS

FIG. 1 is an explosive view of a power semiconductor integrated unit;

FIG. 2 is a front view of a flexible printed circuit board;

FIG. 3 is a rear view of a flexible printed circuit board;

FIG. 4 is a front/rear view of a power semiconductor chip;

FIG. 5 is a schematic diagram of a power converter circuit structure;

FIG. 6 is a schematic diagram of another power converter circuit structure;

FIG. 7 is a schematic diagram of a power module based on an integrated unit; and

FIG. 8 is a schematic diagram of a symmetrical gate loop structure for a parallel connection of a plurality of power semiconductor integrated units.

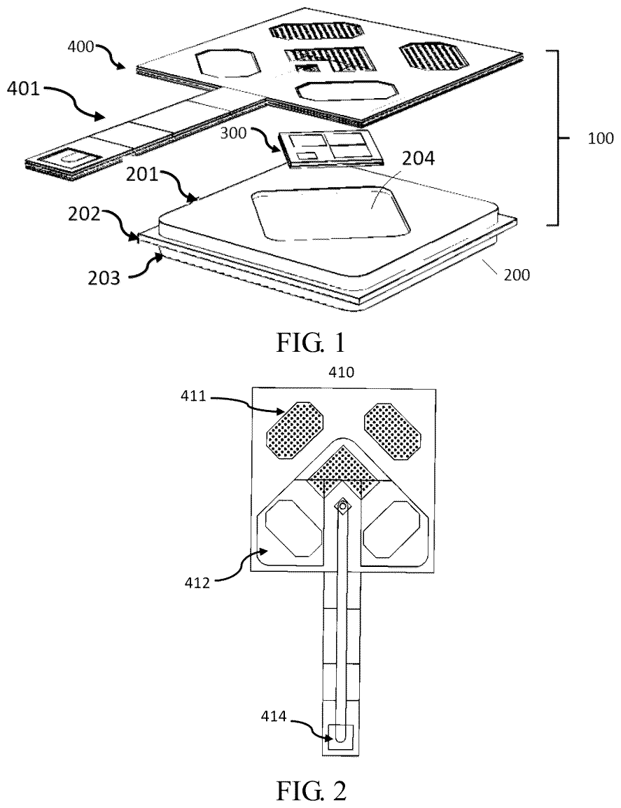

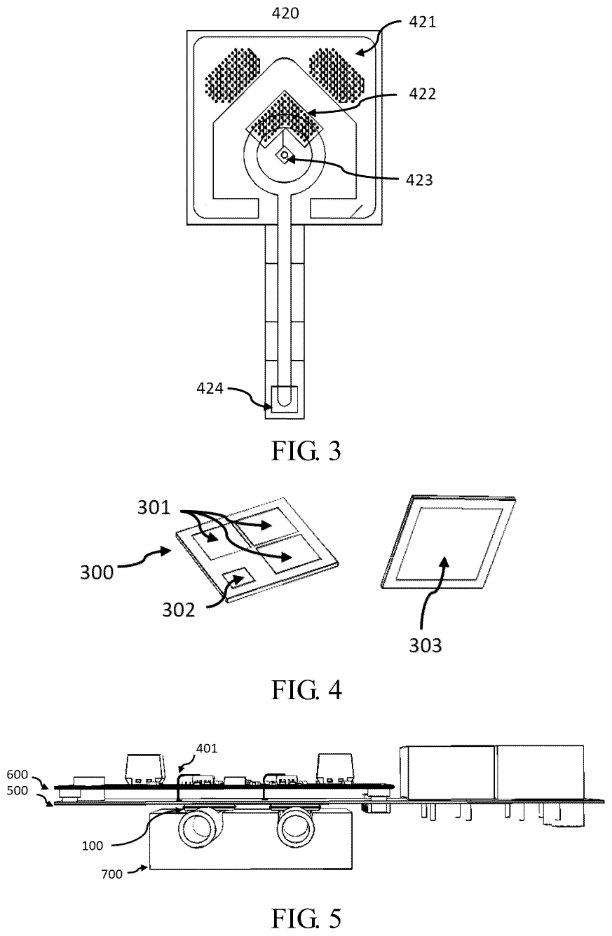

In FIG. 1 to FIG. 6, 100—Power semiconductor integrated unit, 200—Substrate, 202—Base plate, 201—Substrate upper-surface copper layer, 203—Substrate lower-surface copper layer, 204—Recess, 300—Power semiconductor chip, 301—Power semiconductor chip source, 302—Power semiconductor chip gate, 303—Power semiconductor chip drain lower-surface pad, 400—Flexible printed circuit board, 401—Epitaxial portion, 411—Drain upper-surface pad, 412—Source upper-surface pad, 421—Drain lower-surface pad, 422—Source lower-surface pad, 423—Gate pad, 414—Gate solder joint, 424—Source solder joint, 500—Main printed circuit board, 600—Control circuit board, 501—Printed circuit board combining a main circuit and a control circuit, 700—Heat sink, 800—Drive chip, 801—General connection trace, and 900—Power module based on an integrated unit.

### DETAILED DESCRIPTION

The following describes in detail specific implementations of the present invention with reference to the accompanying drawings.

As shown in FIG. 1 to FIG. 4, a power semiconductor integrated unit 100 includes a substrate 200. The substrate 200 is provided with an etched recess to accommodate a power semiconductor chip 300, a bottom surface of the recess is electrically connected to a drain 303 on a bottom surface of the power semiconductor chip 300, and a source 301 and a gate 302 that are on an upper surface of the power semiconductor chip 300 are flush or nearly flush with a top surface of the substrate 200; a flexible printed circuit board 400 is connected to the substrate 200 and the power semiconductor chip 300, the flexible printed circuit board 400 is provided with a source conductive trace and a gate conductive trace, the source conductive trace is connected to the source 301 on a top side of the power semiconductor chip 300, and the gate conductive trace is connected to the gate 302 on the top side of the power semiconductor chip 300; the flexible printed circuit board 400 is provided with an epitaxial portion 401, and the gate conductive trace and the source conductive trace extend onto the epitaxial portion 401; and the epitaxial portion 401 of the flexible printed circuit board 400 is bendable or is directly connected to a power semiconductor control circuit.

A lower layer of the substrate 200 is a thermally-conductive metal layer 203, a middle layer of the substrate is a ceramic insulation layer 202, an upper layer of the substrate is an electrically-conductive metal layer 201, the etched downward recess 204 is provided on the middle of the electrically-conductive metal layer 201, a recess area is larger than a power semiconductor chip area, the downward recess is larger than an insulating material for partially filling the power semiconductor chip, and an upper surface of the electrically-conductive metal layer 201 is almost on the same horizontal plane with the source 301 and the gate 302 that are on the surface of the power semiconductor chip 300; and a drain lower-surface pad 421 on a bottom surface 420 of the flexible printed circuit board 400 is electrically connected to the electrically-conductive metal layer 201 on the upper layer of the substrate.

The source 301 of the power semiconductor chip is electrically connected to a source lower-surface pad 422 on an end portion of the source conductive trace on the bottom surface 420 of the flexible printed circuit board; and the gate 302 of the power semiconductor chip is electrically connected to a gate pad 423 on an end portion of the gate conductive trace on the bottom surface 420 of the flexible printed circuit board.

A board body of the flexible printed circuit board 400 is made of a highly-insulating and flexible film material. A drain upper-surface pad 411 of the flexible printed circuit board 400 is electrically connected to the drain lower-surface pad 421 through a through hole, and a source upper-surface pad 412 of the flexible printed circuit board 400 is electrically connected to a source lower-surface pad 422 through a through hole.

The drain upper-surface pad 411 and the source upper-surface pad 412 that are on an upper surface of the flexible printed circuit board 400 are directly electrically connected to two corresponding positions of a circuit of a power converter, as external power connection points packaged in the power semiconductor, and a gate solder joint 414 and a source solder joint 424 that are of the epitaxial portion 401 of the flexible printed circuit board are directly connected to a gate drive circuit of the power converter, as external control connection points packaged in the power semiconductor.

As shown in FIG. 5, a power converter circuit structure including the power semiconductor integrated unit on the printed circuit board is provided, where an upper surface of the integrated unit 100 is electrically connected to a bottom surface of a main circuit 501, the epitaxial portion 401 of the integrated unit 100 is bent and penetrates a main circuit board 500, and is electrically connected to a control circuit on the main circuit board 500, the drain upper-surface pad 411 and the source upper-surface pad 412 that are on the upper surface 410 of the flexible printed circuit board 400 in the integrated unit 100, as external electrical connection points of the integrated unit, are electrically connected to the main circuit 501 on the main circuit board 500, and the lower surface 203 of the substrate 200 in the integrated unit 100 is partially electrically insulated from a circuit of the integrated unit. The lower surface 203 of the substrate 200 is directly connected to a heat sink 700.

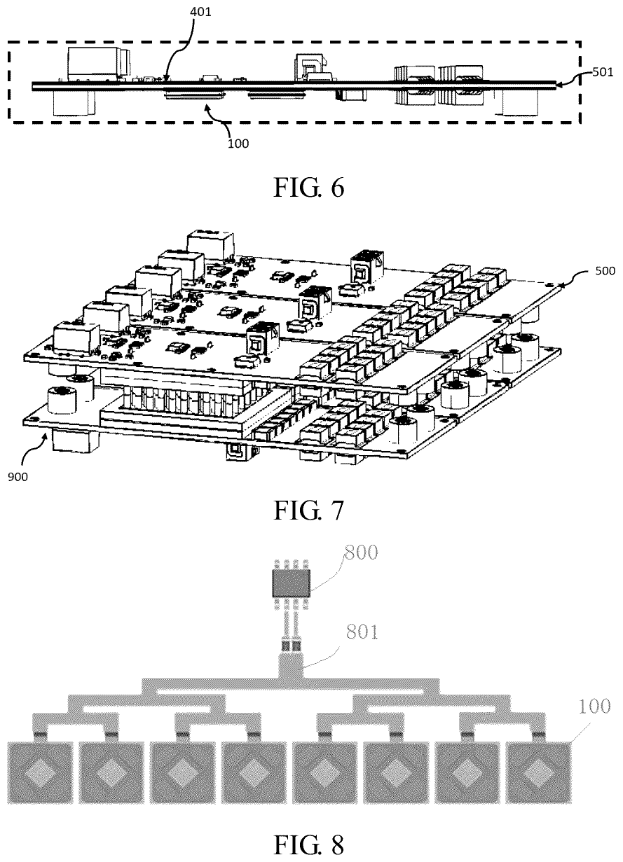

As shown in FIG. 6, another power converter circuit structure including the foregoing power semiconductor integrated unit on the printed circuit board differs from the foregoing power converter circuit structure in that: The control circuit is provided on a control circuit board 600, the control circuit board 600 is disposed on the main circuit board 500, and the epitaxial portion 401 of the flexible printed circuit board 400 in the integrated unit 100 is bent and penetrates the main circuit board 500, and is electrically connected to the control circuit board 600.

As shown in FIG. 7, a power module 900 based on an integrated unit includes a plurality of main circuit boards 500 based on the integrated unit 100 that are connected in parallel.

As shown in FIG. 8, a loop structure with a plurality of power semiconductor integrated units connected in parallel includes the plurality of power semiconductor integrated units 100. Every two of all the power semiconductor integrated units 100 are completely coupled, symmetrically provided, and connected in parallel to form a primary unit, every two primary units are completely coupled, symmetrically provided, and connected in parallel to form a secondary unit, and every two lower units are completely coupled, symmetrically provided, and connected in parallel to form an upper unit, and are finally connected to the same drive chip/circuit 800 through a general connection trace 801.

The foregoing embodiments are merely exemplary descriptions of principles and effects of the present invention and some applied embodiments, but are not intended to limit the present invention. It should be noted that several transformations and improvements may be made by a person of ordinary skill in the art without departing from the concept of the present invention. These transformations and improvements fall within the protection scope of the present invention.

1. A power semiconductor integrated unit on a printed circuit board, comprising a substrate, wherein the substrate is provided with an etched recess to accommodate a power semiconductor ,chip, a bottom surface of the recess is electrically connected to a drain on a bottom surface of the power semiconductor chip, and a source and a gate that are on an upper surface of the power semiconductor chip are flush or nearly flush with a top surface of the substrate; a flexible printed circuit board is connected to the substrate and the power semiconductor chip, the flexible printed circuit board is provided with a source conductive trace and a gate conductive trace, the source conductive trace is connected to the source on a top side of the power semiconductor chip, and the gate conductive trace is connected to the gate on the top side of the power semiconductor chip; the flexible printed circuit board is provided with an epitaxial portion, and the gate conductive trace and the source conductive trace extend onto the epitaxial portion; and the epitaxial portion of the flexible printed circuit board is bendable or is directly connected to a power semiconductor control circuit.

2. The power semiconductor integrated unit on a printed circuit board according to claim 1, wherein a lower layer of the substrate is a thermally-conductive metal layer, a middle layer of the substrate is a ceramic insulation layer, an upper layer of the substrate is an electrically-conductive metal layer, the etched downward recess is provided on the middle of the electrically-conductive metal layer, a recess area is larger than a power semiconductor chip area, and an upper surface of the electrically-conductive metal layer is almost on the same horizontal plane with the source and the gate that are on the surface of the power semiconductor chip; and a drain lower-surface pad on a bottom surface of the flexible printed circuit board is electrically connected to the electrically-conductive metal layer on the upper layer of the substrate.

3. The power semiconductor integrated unit on the printed circuit board according to claim 2, wherein the source of the power semiconductor chip is electrically connected to a source lower-surface pad on an end portion of the source conductive trace on the bottom surface of the flexible printed circuit board; and the gate of the power semiconductor chip is electrically connected to a gate pad on an end portion of the gate conductive trace on the bottom surface of the flexible printed circuit board.

4. The power semiconductor integrated unit on the printed circuit board according to claim 2, wherein a drain upper-surface pad of the flexible printed circuit board is electrically connected to the drain lower-surface pad through a through hole, and a source upper-surface pad of the flexible printed circuit board is electrically connected to a source lower-surface pad through a through hole.

5. The power semiconductor integrated unit on the printed circuit board according to claim 4, wherein the drain upper-surface pad and the source upper-surface pad that are on an upper surface of the flexible printed circuit board are directly electrically connected to two corresponding positions of a circuit of a power converter, as external power connection points packaged in the power semiconductor, and a gate solder joint and a source solder joint that are of the epitaxial portion of the flexible printed circuit board are directly connected to a gate drive circuit of the power converter, as external control connection points packaged in the power semiconductor.

6. The power semiconductor integrated unit on the printed circuit board according to claim 2, wherein the downward recess is larger than an insulating material for partially filling the power semiconductor chip; and a board body of the flexible printed circuit board is made of a highly-insulating and flexible film material.

7. A power converter circuit structure comprising the power semiconductor integrated unit on the printed circuit board according to claim 5, wherein an upper surface of the integrated unit is electrically connected to a bottom surface of a main circuit, the epitaxial portion of the integrated unit is bent and penetrates a main circuit board, and is electrically connected to a control circuit on the main circuit board, the drain upper-surface pad and the source upper-surface pad that are on the upper surface of the flexible printed circuit board in the integrated unit, as external electrical connection points of the integrated unit, are electrically connected to the main circuit on the main circuit board, and the lower surface of the substrate in the integrated unit is partially electrically insulated from a circuit of the integrated unit.

8. The power converter circuit structure comprising the power semiconductor integrated unit on the printed circuit board according to claim 7, wherein the lower surface of the substrate is directly connected to a heat sink.

9. The power converter circuit structure comprising the power semiconductor integrated unit on the printed circuit board according to claim 7, wherein the control circuit is provided on a control circuit board, the control circuit board is disposed on the main circuit board, and the epitaxial portion of the flexible printed circuit board in the integrated unit is bent and penetrates the main circuit board, and is electrically connected to the control circuit board.

10. A loop structure with a plurality of power semiconductor integrated units connected in parallel, comprising the plurality of power semiconductor integrated units according to claim 1, wherein drive circuits of every two of all the power semiconductor integrated units are symmetrically provided and connected in parallel to form a primary unit, drive circuits of every two primary units are symmetrically provided and connected in parallel to form a secondary unit, and drive circuits of every two lower units are symmetrically provided and connected in parallel to form an upper unit, and are finally connected to the same drive chip/circuit through a general connection trace.

11. A loop structure with a plurality of power semiconductor integrated units connected in parallel, comprising the plurality of power semiconductor integrated units according to claim 2, wherein drive circuits of every two of all the power semiconductor integrated units are symmetrically provided and connected in parallel to form a primary unit, drive circuits of every two primary units are symmetrically provided and connected in parallel to form a secondary unit, and drive circuits of every two lower units are symmetrically provided and connected in parallel to form an upper unit, and are finally connected to the same drive chip/circuit through a general connection trace.

12. A loop structure with a plurality of power semiconductor integrated units connected in parallel, comprising the plurality of power semiconductor integrated units according to claim 3, wherein drive circuits of every two of all the power semiconductor integrated units are symmetrically provided and connected in parallel to form a primary unit, drive circuits of every two primary units are symmetrically provided and connected in parallel to form a secondary unit, and drive circuits of every two lower units are symmetrically provided and connected in parallel to form an upper unit, and are finally connected to the same drive chip/circuit through a general connection trace.

13. A loop structure with a plurality of power semiconductor integrated units connected in parallel, comprising the plurality of power semiconductor integrated units according to claim 4, wherein drive circuits of every two of all the power semiconductor integrated units are symmetrically provided and connected in parallel to form a primary unit, drive circuits of every two primary units are symmetrically provided and connected in parallel to form a secondary unit, and drive circuits of every two lower units are symmetrically provided and connected in parallel to form an upper unit, and are finally connected to the same drive chip/circuit through a general connection trace.

14. A loop structure with a plurality of power semiconductor integrated units connected in parallel, comprising the plurality of power semiconductor integrated units according to claim 5, wherein drive circuits of every two of all the power semiconductor integrated units are symmetrically provided and connected in parallel to form a primary unit, drive circuits of every two primary units are symmetrically provided and connected in parallel to form a secondary unit, and drive circuits of every two lower units are symmetrically provided and connected in parallel to form an upper unit, and are finally connected to the same drive chip/circuit through a general connection trace.

15. A loop structure with a plurality of power semiconductor integrated units connected in parallel, comprising the plurality of power semiconductor integrated units according to claim 6, wherein drive circuits of every two of all the power semiconductor integrated units are symmetrically provided and connected in parallel to form a primary unit, drive circuits of every two primary units are symmetrically provided and connected in parallel to form a secondary unit, and drive circuits of every two lower units are symmetrically provided and connected in parallel to form an upper unit, and are finally connected to the same drive chip/circuit through a general connection trace.

16. A loop structure with a plurality of power semiconductor integrated units connected in parallel, comprising the plurality of power semiconductor integrated units according to claim 7, wherein drive circuits of every two of all the power semiconductor integrated units are symmetrically provided and connected in parallel to form a primary unit, drive circuits of every two primary units are symmetrically provided and connected in parallel to form a secondary unit, and drive circuits of every two lower units are symmetrically provided and connected in parallel to form an upper unit, and are finally connected to the same drive chip/circuit through a general connection trace.

17. A loop structure with a plurality of power semiconductor integrated units connected in parallel, comprising the plurality of power semiconductor integrated units according to claim 8, wherein drive circuits of every two of all the power semiconductor integrated units are symmetrically provided and connected in parallel to form a primary unit, drive circuits of every two primary units are symmetrically provided and connected in parallel to form a secondary unit, and drive circuits of every two lower units are symmetrically provided and connected in parallel to form an upper unit, and are finally connected to the same drive chip/circuit through a general connection trace.

18. A loop structure with a plurality of power semiconductor integrated units connected in parallel, comprising the plurality of power semiconductor integrated units according to claim 9, wherein drive circuits of every two of all the power semiconductor integrated units are symmetrically provided and connected in parallel to form a primary unit, drive circuits of every two primary units are symmetrically provided and connected in parallel to form a secondary unit, and drive circuits of every two lower units are symmetrically provided and connected in parallel to form an upper unit, and are finally connected to the same drive chip/circuit through a general connection trace.
